(19) United States
(12) Patent Application Publication
(10) Pub. No.: US 2024/0321968 A1
(43) Pub. Date: Sep. 26, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 18/459,172

(22) Filed: Aug. 31, 2023

(30) Foreign Application Priority Data
Mar. 24, 2023 (JP) 2023-049092

(51) Int. Cl. H01L 29/16; H01L 29/10; H01L 29/78

(52) U.S. Cl. CPC H01L 29/1608; H01L 29/1095; H01L 29/7804

(57) ABSTRACT

A semiconductor device includes a silicon carbide layer having a first silicon carbide region of a first conductivity type, a second silicon carbide region of a second conductivity type, a third silicon carbide region of the second conductivity type, and a fourth silicon carbide region of the first conductivity type, first and second gate electrodes extending in a first direction and provided on a first surface of the silicon carbide layer, a first electrode on the first surface and including a first portion in contact with the third and fourth silicon carbide regions and a second portion in contact with the first silicon carbide region, and a second electrode on a second surface of the silicon carbide layer. The depth of the second silicon carbide region facing the fourth silicon carbide region is shallower than the depth of the second silicon carbide region facing the first gate electrode.

### CROSS-REFERENCE TO RELATED APPLICATION(S)

This application is based upon and claims the benefit of priority from Japanese Patent Application No. 2023-049092, filed Mar. 24, 2023, the entire contents of which are incorporated herein by reference.

### FIELD

Embodiments described herein relate generally to a semiconductor device.

### BACKGROUND

Silicon carbide is a material for semiconductor devices. Silicon carbide has excellent physical properties as compared to silicon such as about three times the bandgap, about ten times the breakdown field strength, and about three times the thermal conductivity. By utilizing such properties, for example, a metal oxide semiconductor field effect transistor (MOSFET) capable of high breakdown voltage, low loss, and high temperature operation can be achieved.

A vertical MOSFET using silicon carbide has a pn junction diode as a built-in diode. For example, a MOSFET is used as a switching element connected to an inductive load. Here, even if the MOSFET is turned off, it is possible to allow a return current to flow by using the pn junction diode.

However, when the return current flows using the pn junction diode that operates in a bipolar manner, stacking faults grow in the silicon carbide layer due to recombination energy of carriers. The growth of stacking faults in the silicon carbide layer causes a problem of increased on-resistance of the MOSFET. The increase in the on-resistance of the MOSFET leads to a deterioration of the reliability of the MOSFET. For example, by providing a Schottky barrier diode (SBD) that operates in a unipolar manner as a built-in diode in the MOSFET, it is possible to reduce stacking faults in the silicon carbide layer.

### DESCRIPTION OF THE DRAWINGS

FIG. 1 is a schematic cross-sectional view of a semiconductor device according to a first embodiment.

FIG. 2 is a schematic top view of the semiconductor device of the first embodiment.

FIG. 3 is an enlarged schematic cross-sectional view of the semiconductor device of the first embodiment.

FIG. 4 is an enlarged schematic cross-sectional view of the semiconductor device of the first embodiment.

FIG. 5 is an enlarged schematic cross-sectional view of the semiconductor device of the first embodiment.

FIG. 6 is an enlarged schematic top view of the semiconductor device of the first embodiment.

FIG. 7 is an equivalent circuit diagram of the semiconductor device of the first embodiment.

FIG. 8 is an enlarged schematic cross-sectional view of a semiconductor device of a comparative example.

FIG. 9 is a diagram for illustrating actions and effects of the semiconductor device of the first embodiment.

FIG. 10 is a diagram for illustrating actions and effects of the semiconductor device of the first embodiment.

FIG. 11 is a schematic cross-sectional view of a semiconductor device according to a second embodiment.

FIG. 12 is a schematic cross-sectional view of the semiconductor device according to the second embodiment.

FIG. 13 is a schematic top view of the semiconductor device of the second embodiment.

FIG. 14 is an enlarged schematic cross-sectional view of the semiconductor device of the second embodiment.

FIG. 15 is an enlarged schematic cross-sectional view of the semiconductor device of the second embodiment.

FIG. 16 is an enlarged schematic cross-sectional view of the semiconductor device of the second embodiment.

FIG. 17 is an enlarged schematic top view of the semiconductor device of the second embodiment.

### DETAILED DESCRIPTION

Embodiments provide a semiconductor device with improved reliability.

In general, according to one embodiment, a semiconductor device includes a silicon carbide layer including a first surface and a second surface on opposite sides of the silicon carbide layer, the silicon carbide layer including a first silicon carbide region of a first conductivity type, a second silicon carbide region of a second conductivity type provided between the first silicon carbide region and the first surface, a third silicon carbide region of the second conductivity type provided between the second silicon carbide region and the first surface and having a second conductivity type impurity concentration higher than a second conductivity type impurity concentration in the second silicon carbide region, and a fourth silicon carbide region of the first conductivity type provided between the second silicon carbide region and the first surface; a first gate electrode extending in a first direction parallel to the first surface and facing the second silicon carbide region; a second gate electrode extending in the first direction, spaced from the first gate electrode in a second direction parallel to the first surface and perpendicular to the first direction, and facing the second silicon carbide region; a first gate insulating layer provided between the second silicon carbide region and the first gate electrode; a second gate insulating layer provided between the second silicon carbide region and the second gate electrode; a first electrode provided on the first surface side of the silicon carbide layer, the first electrode including a first portion provided between the first gate electrode and the second gate electrode and in contact with the third silicon carbide layer and the fourth silicon carbide region, and a second portion provided between the first gate electrode and the second gate electrode, spaced from the first portion in the first direction, and in contact with the first silicon carbide region; and a second electrode provided on the second surface side of the silicon carbide layer, in which the first silicon carbide region includes a first region, and second, third, and fourth regions provided between the first region and the second silicon carbide region, a first conductivity type impurity concentration in the second region is higher than a first conductivity type impurity concentration in the first region, a first conductivity type impurity concentration in the third region is higher than the first conductivity type impurity concentration in the first region, the second silicon carbide region includes a fifth region facing the first gate electrode, a sixth region facing the second gate electrode, and a seventh region provided between the fifth region and the sixth region and having a shallower depth than a depth of the fifth region and a depth of the sixth region, the second region is provided between the first region and the fifth region, the third region is provided between the first region and the sixth region, and the fourth region is provided between the first region and the seventh region.

Hereinafter, embodiments of the present disclosure will be described with reference to the drawings. In the following description, the same or similar members and the like are denoted by the same reference numerals, and the description of the members and the like that have already been described may be omitted as appropriate.

In the following description, n⁺, n, n⁻, and p⁺, p, p⁻ represent a relative level of impurity concentration in each conductivity type. That is, n⁺ indicates a relatively higher n-type impurity concentration than n, and n⁻ indicates a relatively lower n-type impurity concentration than n. p⁺ indicates a relatively higher p-type impurity concentration than p, and p⁻ indicates a relatively lower p-type impurity concentration than p. Sometimes, n⁺ type and n⁻ type are simply referred to as n type, and p⁺ type and p⁻ type are simply referred to as p type.

The impurity concentration may be measured by, for example, the secondary ion mass spectrometry (SIMS). The relative level of the impurity concentration may be determined from a level of the carrier concentration obtained by, for example, the scanning capacitance microscopy (SCM). Distances such as width and depth of the impurity region may be obtained by SIMS, for example. Distances such as the width and depth of the impurity region may be obtained from, for example, an SCM image or a scanning electron microscope (SEM) image. The thickness of the insulating layer and the like may be measured on an image of SIMS, SEM, or transmission electron microscope (TEM), for example.

In the specification, “p-type impurity concentration” of the p-type silicon carbide region means a net p-type impurity concentration obtained by subtracting the n-type impurity concentration of the region from the p-type impurity concentration of the region. “n-type impurity concentration” of the n-type silicon carbide region means a net n-type impurity concentration obtained by subtracting the p-type impurity concentration of the region from the n-type impurity concentration of the region.

Unless otherwise stated in the specification, the impurity concentration of a specific region means the maximum impurity concentration of that region.

### First Embodiment

A semiconductor device according to a first embodiment includes a silicon carbide layer including a first surface and a second surface facing the first surface, the silicon carbide layer including a first silicon carbide region of a first conductivity type, a second silicon carbide region of a second conductivity type provided between the first silicon carbide region and the first surface, a third silicon carbide region of the second conductivity type provided between the second silicon carbide region and the first surface and having a second conductivity type impurity concentration higher than the second conductivity type impurity concentration in the second silicon carbide region, and a fourth silicon carbide region of the first conductivity type provided between the second silicon carbide region and the first surface and in contact with the first surface; a first gate electrode extending in a first direction parallel to the first surface and facing the second silicon carbide region; a second gate electrode extending in the first direction, provided in a second direction parallel to the first surface and perpendicular to the first direction with respect to the first gate electrode and facing the second silicon carbide region; a first gate insulating layer provided between the second silicon carbide region and the first gate electrode; a second gate insulating layer provided between the second silicon carbide region and the second gate electrode; a first electrode provided on the first surface side of the silicon carbide layer, the first electrode including a first portion provided between the first gate electrode and the second gate electrode and in contact with the third silicon carbide region and the fourth silicon carbide region, and a second portion provided between the first gate electrode and the second gate electrode, provided in the first direction of the first portion, and in contact with the first silicon carbide region; and a second electrode provided on the second surface side of the silicon carbide layer. The first silicon carbide region includes a first region, a second region provided between the first region and the second silicon carbide region, a third region provided between the first region and the second silicon carbide region, and a fourth region provided between the first region and the second silicon carbide region, in which the first conductivity type impurity concentration in the second region is higher than the first conductivity type impurity concentration in the first region, the first conductivity type impurity concentration in the third region is higher than the first conductivity type impurity concentration in the first region, the second silicon carbide region includes a fifth region facing the first gate electrode, a sixth region facing the second gate electrode, and a seventh region provided between the fifth region and the sixth region and having a shallower depth than the depth of the fifth region and the depth of the sixth region, the second region is provided between the first region and the fifth region, the third region is provided between the first region and the sixth region, and the fourth region is provided between the first region and the seventh region.

The semiconductor device of the first embodiment is a planar gate type vertical MOSFET 100 using silicon carbide. The MOSFET 100 of the first embodiment is, for example, a double implantation MOSFET (DIMOSFET) in which a body region and a source region are formed by ion implantation. The MOSFET 100 of the first embodiment includes an SBD as a built-in diode.

An example in which the first conductivity type is the n-type and the second conductivity type is the p-type will be described below. The MOSFET 100 is a vertical n-channel MOSFET that uses electrons as carriers.

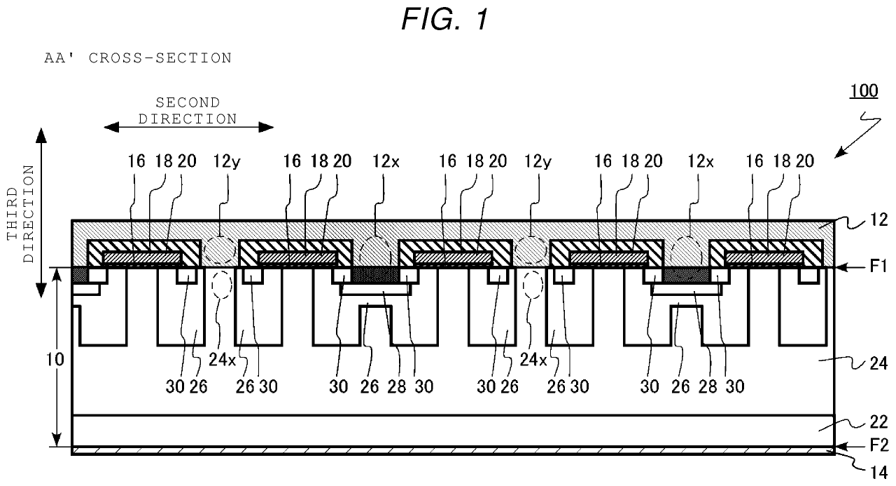

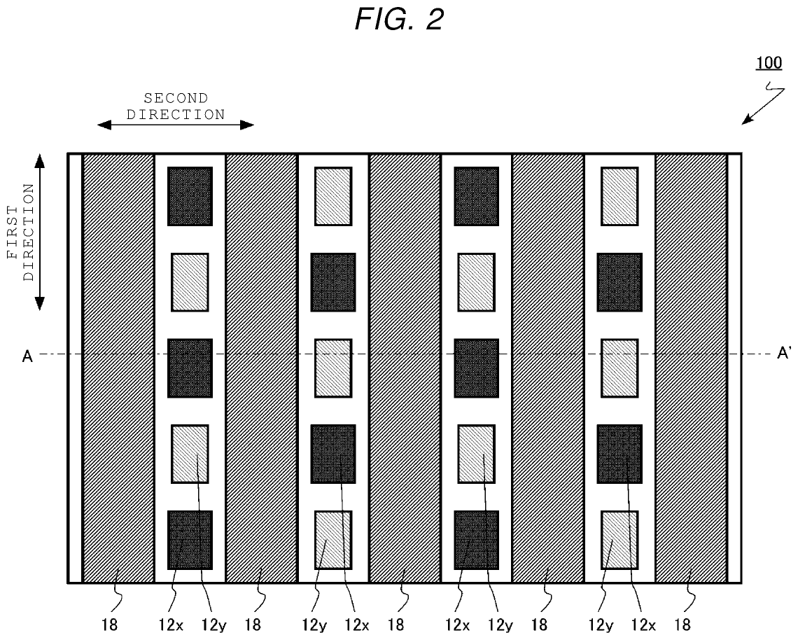

FIG. 1 is a schematic cross-sectional view of a semiconductor device according to the first embodiment. FIG. 2 is a schematic top view of the semiconductor device of the first embodiment. FIG. 2 is a schematic diagram illustrating patterns of gate electrodes and source electrodes on the upper surface of the silicon carbide layer. FIG. 1 is a cross-sectional view taken along line AA′ of FIG. 2.

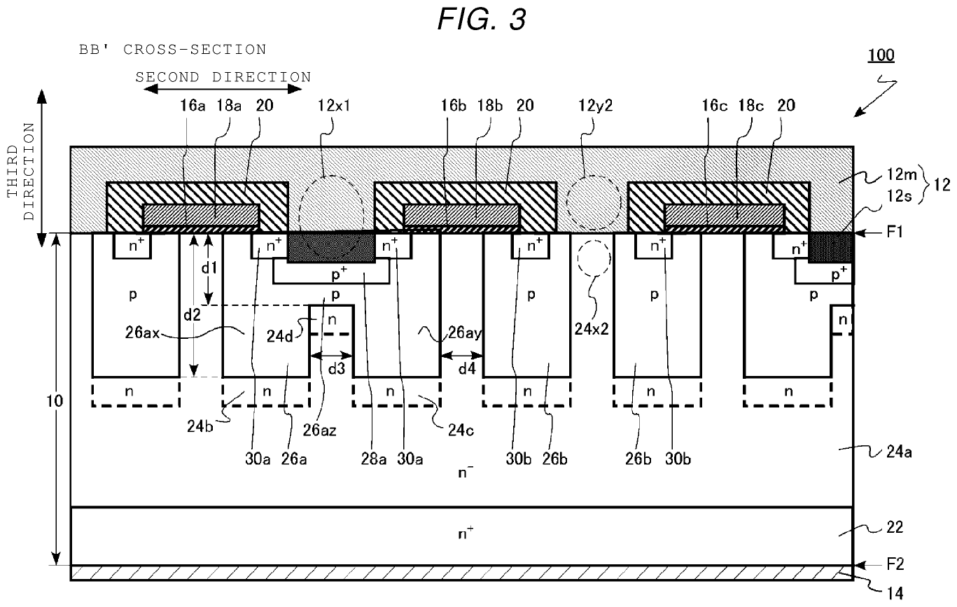

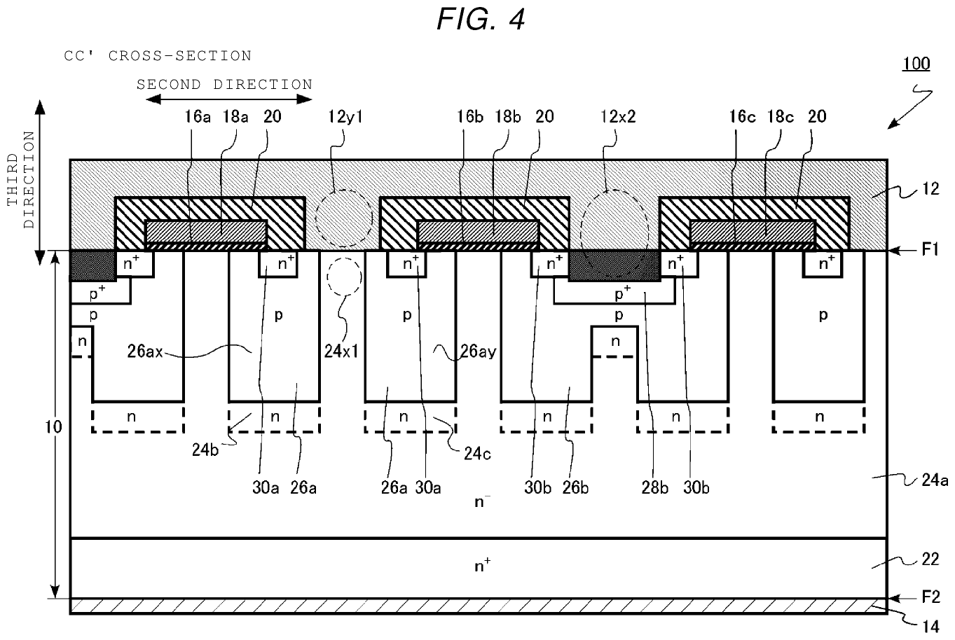

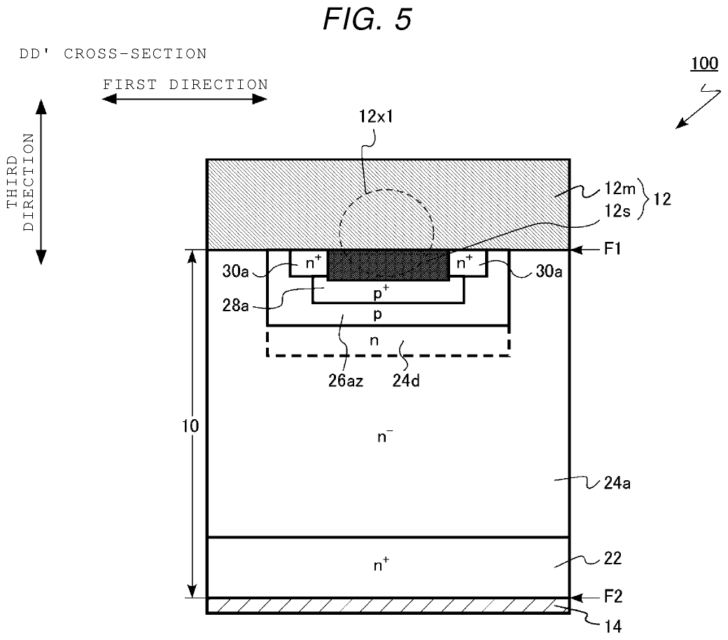

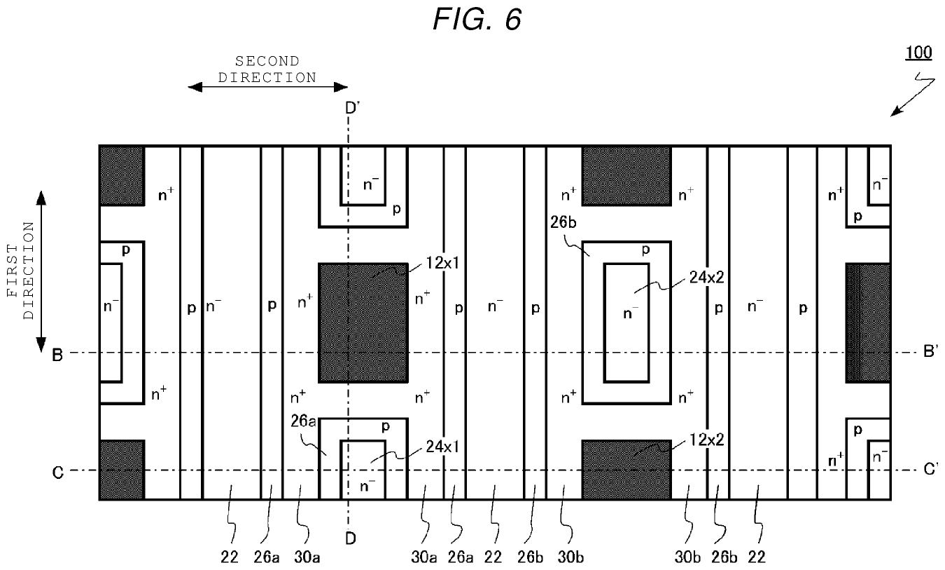

FIGS. 3, 4, and 5 are enlarged schematic cross-sectional views of the semiconductor device of the first embodiment. FIG. 6 is an enlarged schematic top view of the semiconductor device of the first embodiment. FIG. 6 is a diagram illustrating a pattern of a semiconductor region on an upper surface of the silicon carbide layer. FIG. 3 is a cross-sectional view taken along line BB′ of FIG. 6. FIG. 4 is a cross-sectional view taken along line CC′ of FIG. 6. FIG. 5 is a cross-sectional view taken along line DD′ of FIG. 6.

The MOSFET 100 includes a silicon carbide layer 10, a source electrode 12, a drain electrode 14, a gate insulating layer 16, a gate electrode 18, and an interlayer insulating layer 20. The source electrode 12 includes a metal silicide layer 12s and a metal layer 12m. The source electrode 12 includes a contact electrode portion 12x and a diode electrode portion 12y. The contact electrode portion 12x includes a first contact electrode portion 12x1 and a second contact electrode portion 12x2. The diode electrode portion 12y includes a first diode electrode portion 12y1 and a second diode electrode portion 12y2. The gate insulating layer 16 includes a first gate insulating layer 16a, a second gate insulating layer 16b, and a third gate insulating layer 16c. The gate electrode 18 includes a first gate electrode 18a, a second gate electrode 18b, and a third gate electrode 18c.

The silicon carbide layer 10 includes an n⁺-type drain region 22, an n⁻-type drift region 24, a p-type body region 26, a p⁺-type body contact region 28, and an n⁺-type source region 30. The p-type body region 26 includes a p-type first body region 26a and a p-type second body region 26b. The p⁺-type body contact region 28 includes a p⁺-type first body contact region 28a and a p⁺-type second body contact region 28b. The n⁺-type source region 30 includes an n⁺-type first source region 30a and an n⁺-type second source region 30b.

The drift region 24 includes a main region 24a, a first CSL region 24b, a second CSL region 24c, and a third CSL region 24d. CSL is an abbreviation for current spreading layer.

The drift region 24 includes a JBS region 24x. The JBS region 24x includes a first JBS region 24x1 and a second JBS region 24x2. JBS is an abbreviation for junction barrier Schottky.

The first body region 26a includes a first deep region 26ax, a second deep region 26ay, and a shallow region 26az.

The silicon carbide layer 10 is provided between the source electrode 12 and the drain electrode 14. The silicon carbide layer 10 is single crystal SiC. The silicon carbide layer 10 is, for example, 4H—SiC.

The silicon carbide layer 10 includes a first surface (“F1” in FIG. 1) and a second surface (“F2” in FIG. 1). Hereinafter, the first surface F1 may be referred to as an upper surface, and the second surface F2 may be referred to as a lower surface. The first surface F1 is located on the source electrode 12 side of the silicon carbide layer 10. The second surface F2 is located on the drain electrode 14 side of the silicon carbide layer 10. The first surface F1 and the second surface F2 are on opposite surfaces of the silicon carbide layer 10. Hereinafter, “depth” means the depth in the direction from the first surface toward the second surface.

The first direction and the second direction are parallel to the first surface F1. The second direction is perpendicular to the first direction.

The first surface F1 is, for example, a surface inclined from 0 degrees to 8 degrees with respect to a (0001) plane. The second surface F2 is, for example, a surface inclined from 0 degrees to 8 degrees with respect to a (000-1) plane. The (0001) plane is called a silicon surface. The (000-1) plane is called a carbon surface.

The n⁺-type drain region 22 is provided on the lower surface side of the silicon carbide layer 10. The drain region 22 contains, for example, nitrogen (N) as an n-type impurity. The n-type impurity concentration of the drain region 22 is, for example, 1×10¹⁸ cm⁻³ or more and 1×10²¹ cm⁻³ or less.

The n⁻-type drift region 24 is provided between the drain region 22 and the first surface F1. The n⁻-type drift region 24 is provided between the source electrode 12 and the drain electrode 14. The n⁻-type drift region 24 is provided between the gate electrode 18 and the drain electrode 14.

The n⁻-type drift region 24 is provided over the drain region 22. The drift region 24 includes, for example, nitrogen (N) as an n-type impurity. The n-type impurity concentration of the drift region 24 is lower than the n-type impurity concentration of the drain region 22. The n-type impurity concentration of the drift region 24 is, for example, 4×10¹⁴ cm⁻³ or more and 5×10¹⁷ cm⁻³ or less. The thickness of the drift region 24 is, for example, 3 μm or more and 150 μm or less.

The drift region 24 includes the main region 24a, the first CSL region 24b, the second CSL region 24c, and the third CSL region 24d. The first CSL region 24b, the second CSL region 24c, and the third CSL region 24d are provided between the main region 24a and the body region 26. The first CSL region 24b, the second CSL region 24c, and the third CSL region 24d are provided, for example, between the main region 24a and the first body region 26a.

The first CSL region 24b, the second CSL region 24c, and the third CSL region 24d have a function of widening the current path and increasing the ON current, for example, when the MOSFET 100 is turned on or the SBD is turned on.

The first CSL region 24b is provided, for example, between the main region 24a and the first deep region 26ax. The first CSL region 24b contacts, for example, the first deep region 26ax.

The second CSL region 24c is provided, for example, between the main region 24a and the second deep region 26ay. The second CSL region 24c contacts, for example, the second deep region 26ay.

The third CSL region 24d is provided, for example, between the main region 24a and the shallow region 26az. The third CSL region 24d contacts, for example, the shallow region 26az.

The n-type impurity concentration of the first CSL region 24b is higher than the n-type impurity concentration of the main region 24a. The n-type impurity concentration of the first CSL region 24b is, for example, 1×10¹⁶ cm⁻³ or more and 5×10¹⁷ cm⁻³ or less.

The n-type impurity concentration of the second CSL region 24c is higher than the n-type impurity concentration of the main region 24a. The n-type impurity concentration of the second CSL region 24c is, for example, 1×10¹⁶ cm⁻³ or more and 5×10¹⁷ cm⁻³ or less.

The n-type impurity concentration of the third CSL region 24d is, for example, higher than the n-type impurity concentration of the main region 24a. The n-type impurity concentration of the third CSL region 24d is, for example, higher than the n-type impurity concentration of the first CSL region 24b and the n-type impurity concentration of the second CSL region 24c. The n-type impurity concentration of the third CSL region 24d is, for example, 1.5 to 10 times the n-type impurity concentration of the first CSL region 24b and the n-type impurity concentration of the second CSL region 24c. The n-type impurity concentration of the third CSL region 24d is, for example, 1.5×10¹⁶ cm⁻³ or more and 5×10¹⁷ cm⁻³ or less.

The drift region 24 includes the JBS region 24x. The JBS region 24x includes the first JBS region 24x1 and the second JBS region 24x2.

The JBS region 24x is at and below the first surface F1. The JBS region 24x is surrounded by the body region 26. For example, the first JBS region 24x1 is surrounded by the first body region 26a. For example, the second JBS region 24x2 is surrounded by the second body region 26b.

The JBS region 24x contacts the diode electrode portion 12y of the source electrode 12. For example, the first JBS region 24x1 contacts the first diode electrode portion 12y1. For example, the second JBS region 24x2 contacts the second diode electrode portion 12y2. The JBS region 24x functions as a cathode region of the SBD.

The p-type body region 26 is provided between the drift region 24 and the first surface F1. The body region 26 extends in the first direction. The body region 26 functions as a channel region of the MOSFET 100.

The first body region 26a is provided between the drift region 24 and the first surface F1. The second body region 26b is provided between the drift region 24 and the first surface F1. The second body region 26b is spaced apart from the first body region 26a in the second direction.

The body region 26 includes, for example, aluminum (Al) as a p-type impurity.

The p-type impurity concentration of the body region 26 is, for example, 5×10¹⁶ cm⁻³ or more and 5×10¹⁸ cm⁻³ or less.

The depth of the body region 26 is, for example, 500 nm or more and 2 μm or less.

The body region 26 is electrically connected to the source electrode 12. The body region 26 is fixed at the potential of the source electrode 12.

A part of the body region 26 is at the first surface F1. A part of the body region 26 faces the gate electrode 18. A part of the body region 26 becomes a channel region of the MOSFET 100. The gate insulating layer 16 is sandwiched between a part of the body region 26 and the gate electrode 18.

The first body region 26a includes the first deep region 26ax, the second deep region 26ay, and the shallow region 26az.

The first deep region 26ax faces the first gate electrode 18a at the first surface F1. The second deep region 26ay faces the second gate electrode 18b at the first surface F1.

The shallow region 26az is provided between the first deep region 26ax and the second deep region 26ay. The shallow region 26az is provided between the first body contact region 28a and the drift region 24. The shallow region 26az is provided between the first body contact region 28a and the third CSL region 24d.

The depth of the shallow region 26az (d1 in FIG. 3) is shallower than the depth of the first deep region 26ax (d2 in FIG. 3) and the depth of the second deep region 26ay (d2 in FIG. 3). The depth of the shallow region 26az (d1 in FIG. 3) is, for example, one half or less and one-tenth or more of the depth of the first deep region 26ax (d2 in FIG. 3) and the depth of the second deep region 26ay (d2 in FIG. 3).

The depth of the first deep region 26ax (d2 in FIG. 3) and the depth of the second deep region 26ay (d2 in FIG. 3) are, for example, 1.5 μm or more and 2 μm or less. The depth of the shallow region 26az (d1 in FIG. 3) is, for example, 0.5 μm or more and 1 μm or less.

The distance from the second surface F2 to the shallow region 26az is greater than the distance from the second surface F2 to the first deep region 26ax. The distance from the second surface F2 to the shallow region 26az is greater than the distance from the second surface F2 to the second deep region 26ay.

The distance in the second direction between the first deep region 26ax and the second deep region 26ay (d3 in FIG. 3) is, for example, greater than the distance in the second direction between the first body region 26a and the second body region 26b (d4 in FIG. 3). The distance in the second direction between the first deep region 26ax and the second deep region 26ay (d3 in FIG. 3) is, for example, 1.2 times or more and twice or less of the distance in the second direction between the first body region 26a and the second body region 26b (d4 in FIG. 3).

The p⁺-type body contact region 28 is provided between the body region 26 and the first surface F1. The body contact region 28 is provided between the body region 26 and the contact electrode portion 12x of the source electrode 12.

The first body contact region 28a is provided between the first body region 26a and the first surface F1. The first body contact region 28a is provided between the first body region 26a and the first contact electrode portion 12x1.

The first body contact region 28a is provided between the shallow region 26az and the source electrode 12.

The second body contact region 28b is provided between the second body region 26b and the first surface F1. The second body contact region 28b is provided between the second body region 26b and the second contact electrode portion 12x2.

The p-type impurity concentration of the body contact region 28 is higher than the p-type impurity concentration of the body region 26.

The body contact region 28 includes, for example, aluminum (Al) as a p-type impurity. The p-type impurity concentration of the body contact region 28 is, for example, 1×10¹⁹ cm⁻³ or more and 5×10²⁰ cm⁻³ or less.

The depth of the body contact region 28 is, for example, 200 nm or more and 700 nm or less.

The body contact region 28 contacts the source electrode 12. The body contact region 28 is electrically connected to the source electrode 12. A contact between the body contact region 28 and the source electrode 12 is, for example, an ohmic contact. The body contact region 28 is fixed at the potential of the source electrode 12.

The body contact region 28 contacts the contact electrode portion 12x of the source electrode 12. The first body contact region 28a contacts the first contact electrode portion 12x1. The second body contact region 28b contacts the second contact electrode portion 12x2.

The n⁺-type source region 30 is provided between the body region 26 and the first surface F1. The n⁺-type source region 30 is provided, for example, between the body contact region 28 and the first surface F1.

The first source region 30a is provided between the first body region 26a and the first surface F1. The first source region 30a is provided, for example, between the first body contact region 28a and the first surface F1.

The second source region 30b is provided between the second body region 26b and the first surface F1. The second source region 30b is provided, for example, between the second body contact region 28b and the first surface F1.

The source region 30 contains, for example, phosphorus (P) or nitrogen (N) as an n-type impurity. The n-type impurity concentration of the source region 30 is higher than the n-type impurity concentration of the drift region 24.

The n-type impurity concentration of the source region 30 is, for example, 1×10¹⁹ cm⁻³ or more and 5×10²¹ cm⁻³ or less. The depth of the source region 30 is shallower than the depth of the body region 26. The depth of the source region 30 is, for example, 80 nm or more and 200 nm or less.

The source region 30 contacts the source electrode 12. The source region 30 is electrically connected to the source electrode 12. The contact between the source region 30 and the source electrode 12 is, for example, an ohmic contact. The source region 30 is fixed at the potential of the source electrode 12.

The source region 30 contacts the contact electrode portion 12x of the source electrode 12. The first source region 30a contacts the first contact electrode portion 12x1. The second source region 30b contacts the second contact electrode portion 12x2.

The gate electrode 18 is provided on the first surface F1 side of the silicon carbide layer 10. The gate electrode 18 extends in the first direction. A plurality of gate electrodes 18 extending parallel to each other are arranged in the second direction. The gate electrode 18 faces the body region 26 on the first surface F1.

The first gate electrode 18a extends in the first direction. The first gate electrode 18a faces the first body region 26a with the first surface F1 therebetween.

The second gate electrode 18b extends in the first direction. The second gate electrode 18b is spaced in the second direction with respect to the first gate electrode 18a. The second gate electrode 18b faces the first body region 26a and the second body region 26b with the first surface F1 therebetween.

The third gate electrode 18c extends in the first direction. The third gate electrode 18c is spaced in the second direction with respect to the second gate electrode 18b. The second gate electrode 18b is provided between the first gate electrode 18a and the third gate electrode 18c. The third gate electrode 18c faces the second body region 26b with the first surface F1 therebetween.

The gate electrode 18 is a conductive layer. The gate electrode 18 is, for example, polycrystalline silicon containing p-type impurities or n-type impurities.

The gate insulating layer 16 is provided between the gate electrode 18 and the body region 26. The first gate insulating layer 16a is provided between the first gate electrode 18a and the first body region 26a. The second gate insulating layer 16b is provided between the second gate electrode 18b and the first body region 26a. The second gate insulating layer 16b is provided between the second gate electrode 18b and the second body region 26b. The third gate insulating layer 16c is provided between the third gate electrode 18c and the second body region 26b.

The gate insulating layer 16 contains, for example, silicon oxide. The gate insulating layer 16 includes, for example, a silicon oxide layer. A high dielectric constant insulating material, for example, may be applied to the gate insulating layer 16. A stacked structure of a silicon oxide layer and a high dielectric constant insulating layer, for example, may be applied to the gate insulating layer 16.

The thickness of the gate insulating layer 16 is, for example, 30 nm or more and 100 nm or less.

The interlayer insulating layer 20 is provided on the gate electrode 18. The interlayer insulating layer 20 is provided between the gate electrode 18 and the source electrode 12.

The interlayer insulating layer 20 electrically separates the gate electrode 18 and the source electrode 12. The interlayer insulating layer 20 contains, for example, silicon oxide. The interlayer insulating layer 20 is, for example, a silicon oxide layer.

The source electrode 12 is provided on the first surface F1 side of the silicon carbide layer 10. The source electrode 12 is in contact with the silicon carbide layer 10. The source electrode 12 contacts the body contact region 28 and the source region 30.

The source electrode 12 includes the contact electrode portion 12x and the diode electrode portion 12y.

The contact electrode portion 12x is provided between two gate electrodes 18. The contact electrode portion 12x contacts the body contact region 28 and the source region 30.

For example, the interface between the contact electrode portion 12x and the body contact region 28 is located inwardly from the first surface F1 toward the second surface F2 in a third direction perpendicular to the first surface F1. For example, the contact electrode portion 12x contacts the source region 30 in the second direction.

The first contact electrode portion 12x1 is provided between the first gate electrode 18a and the second gate electrode 18b. The first contact electrode portion 12x1 contacts the first body contact region 28a and the first source region 30a.

For example, the interface between the first contact electrode portion 12x1 and the first body contact region 28a is located inwardly from the first surface F1 toward the second surface F2 in the third direction perpendicular to the first surface F1. For example, the first contact electrode portion 12x1 contacts the first source region 30a in the second direction.

The second contact electrode portion 12x2 is provided between the second gate electrode 18b and the third gate electrode 18c. The second contact electrode portion 12x2 contacts the second body contact region 28b and the second source region 30b.

For example, the interface between the second contact electrode portion 12x2 and the second body contact region 28b is located inwardly from the first surface F1 toward the second surface F2 in the third direction perpendicular to the first surface F1. For example, the second contact electrode portion 12x2 contacts the second source region 30b in the second direction.

The diode electrode portion 12y is provided between two gate electrodes 18. The diode electrode portion 12y is spaced in the first direction from the contact electrode portion 12x.

The contact electrode portion 12x and the diode electrode portion 12y are alternately and repeatedly located in the first direction between the same two gate electrodes 18.

The diode electrode portion 12y contacts the JBS region 24x of the drift region 24. The diode electrode portion 12y functions as an anode electrode of the SBD.

The first diode electrode portion 12y1 is provided between the first gate electrode 18a and the second gate electrode 18b. The first diode electrode portion 12y1 is spaced in the first direction from the first contact electrode portion 12x1. The first diode electrode portion 12y1 contacts the first JBS region 24x1 of the drift region 24.

The second diode electrode portion 12y2 is provided between the second gate electrode 18b and the third gate electrode 18c. The second diode electrode portion 12y2 is spaced in the first direction from the second contact electrode portion 12x2. The second diode electrode portion 12y2 contacts the second JBS region 24x2 of the drift region 24.

The contact electrode portion 12x is spaced in the second direction from the diode electrode portion 12y. For example, the second contact electrode portion 12x2 is spaced in the second direction from the first diode electrode portion 12y1. For example, the first contact electrode portion 12x1 is spaced in the second direction from the second diode electrode portion 12y2.

In the MOSFET 100, the diode electrode portion 12y and the contact electrode portion 12x are adjacent to each other in the second direction. The position of the contact electrode portion 12x and the diode electrode portion 12y in the first direction is shifted by half a period from the position in the first direction of the contact electrode portion 12x and the diode electrode portion 12y adjacent to each other in the second direction.

In other words, in the MOSFET 100, the diode electrode portion 12y and the contact electrode portion 12x are located in a checkerboard pattern.

The source electrode 12 includes the metal silicide layer 12s and the metal layer 12m. The metal silicide layer 12s is provided between the silicon carbide layer 10 and the metal layer 12m.

The metal silicide layer 12s contacts the body contact region 28. The metal silicide layer 12s contacts the source region 30.

The metal silicide layer 12s contains, for example, nickel (Ni), titanium (Ti), or cobalt (Co). The metal silicide layer 12s is, for example, a nickel silicide layer, a titanium silicide layer, or a cobalt silicide layer.

The metal layer 12m contains metal. The metal layer 12m has, for example, a stacked structure of a barrier metal film and a metal film.

The barrier metal film contains, for example, titanium (Ti), tungsten (W), or tantalum (Ta). The barrier metal film is, for example, a titanium film, a titanium nitride film, a tungsten nitride film, or a tantalum nitride film.

The metal film contains, for example, aluminum (Al). The metal film is, for example, an aluminum film.

The contact electrode portion 12x includes the metal silicide layer 12s. The first contact electrode portion 12x1 includes the metal silicide layer 12s. The second contact electrode portion 12x2 includes the metal silicide layer 12s.

Since the contact electrode portion 12x includes the metal silicide layer 12s, an ohmic contact is established between the source electrode 12 and the body contact region 28 and between the source electrode 12 and the source region 30.

The diode electrode portion 12y includes, for example, a barrier metal film. The first diode electrode portion 12y1 includes, for example, a barrier metal film. The second diode electrode portion 12y2 includes, for example, a barrier metal film.

For example, the diode electrode portion 12y includes a barrier metal film, so that Schottky contact is established between the source electrode 12 and the JBS region 24x.

The drain electrode 14 is provided on the second surface F2 side of the silicon carbide layer 10. The drain electrode 14 is provided on the second surface F2 of the silicon carbide layer 10. The drain electrode 14 is in contact with the second surface F2.

The drain electrode 14 contains, for example, a metal or metal-semiconductor compound. The drain electrode 14 includes, for example, a nickel silicide layer, a titanium layer, a nickel layer, a silver layer, or a gold layer.

The drain electrode 14 is electrically connected to the drain region 22. The drain electrode 14 contacts, for example, the drain region 22.

Next, the action and effect of the MOSFET 100 of the first embodiment will be described.

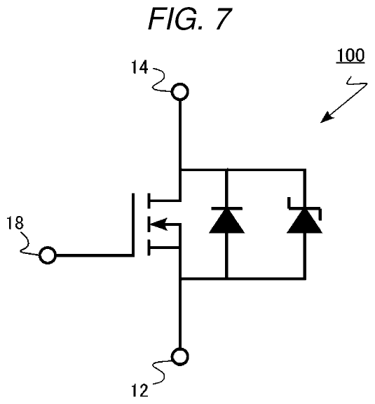

FIG. 7 is an equivalent circuit diagram of the semiconductor device of the first embodiment. In the MOSFET 100, a pn diode and an SBD, as built-in diodes, are connected in parallel to the transistor between the source electrode 12 and the drain electrode 14. The body region 26 is an anode region of a pn junction diode and the drift region 24 is a cathode region of the pn junction diode. The source electrode 12 is the anode electrode of the SBD, and the JBS region 24x is the cathode region of the SBD.

For example, a case where MOSFET 100 is used as a switching device connected to an inductive load is considered. When the MOSFET 100 is turned off, an induced current caused by an inductive load may apply a positive voltage to the source electrode 12 with respect to the drain electrode 14. Here, a forward current flows through the built-in diode. This state is also referred to as reverse conducting state.

If the MOSFET does not include an SBD, a forward current will flow through the pn junction diode. The pn junction diode operates in a bipolar manner. When a return current is passed using the pn junction diode that operates in a bipolar manner, stacking faults grow in the silicon carbide layer due to recombination energy of carriers. The growth of stacking faults in the silicon carbide layer causes a problem of increased on-resistance of the MOSFET. The increase in the on-resistance of the MOSFET leads to a deterioration of the reliability of the MOSFET.

The MOSFET 100 includes an SBD. The forward voltage (Vf) at which a forward current begins to flow through the SBD is lower than the forward voltage (Vf) of the pn junction diode. Therefore, a forward current flows through the SBD before the pn junction diode.

The forward voltage (Vf) of the SBD is, for example, 1.0 V or more and less than 2.0 V. The forward voltage (Vf) of the pn junction diode is, for example, 2.0 V or more and 3.0 V or less.

The SBD operates in a unipolar manner. Therefore, even if a forward current flows, stacking faults do not grow in the silicon carbide layer 10 due to recombination energy of carriers. Therefore, the increase in on-resistance of the MOSFET 100 is suppressed. The reliability of the MOSFET 100 is improved.

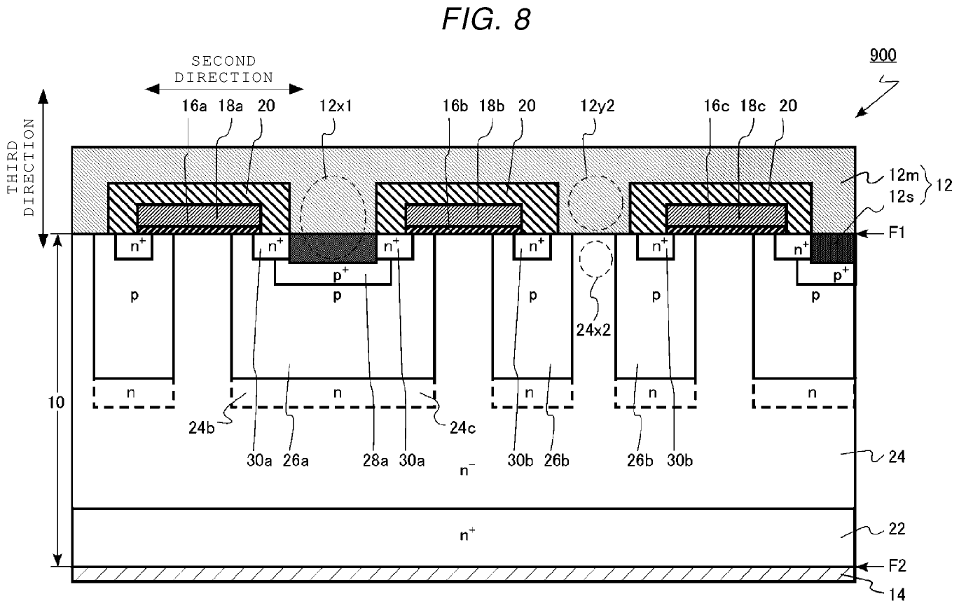

FIG. 8 is an enlarged schematic cross-sectional view of a semiconductor device according to a comparative example. FIG. 8 is a diagram for comparison with FIG. 3 of the first embodiment.

The semiconductor device of the comparative example is a MOSFET 900. The MOSFET 900 differs from the MOSFET 100 of the first embodiment in that the first body region 26a does not include the shallow region 26az and the drift region 24 does not include the third CSL region 24d.

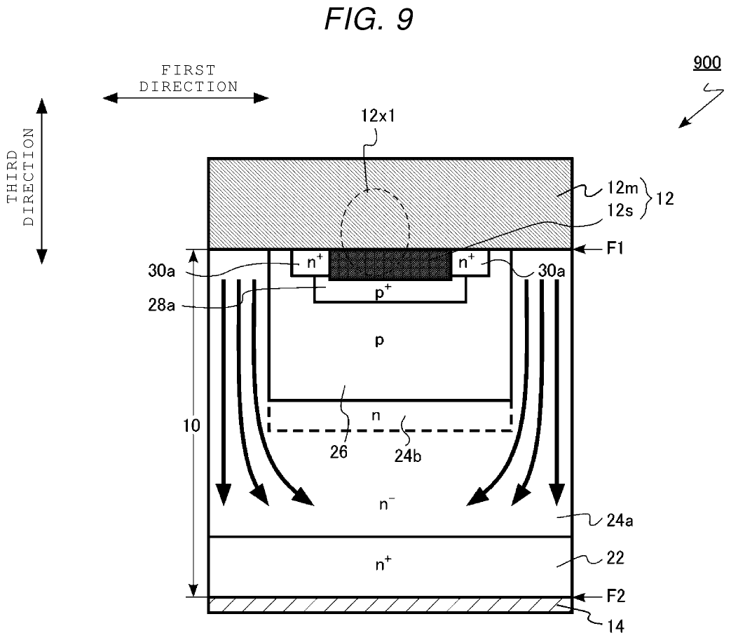

FIG. 9 is a diagram for illustrating the operation and effects of the comparative example. FIG. 9 is a diagram for comparison with FIG. 5 of the first embodiment.

FIG. 9 illustrates a state in which a forward current is flowing through the SBD. The arrow in FIG. 9 indicates the forward current path of the SBD.

As illustrated in FIG. 9, a part of the forward current flows into the bottom of the body region 26 along the CSL region 24b/24c at the bottom of the body region 26 under the first contact electrode portion 12x1. A part of the forward current flows into the bottom of the body region 26, thereby suppressing the lowering of the potential barrier of the pn junction at the bottom of the body region 26. By suppressing the lowering of the potential barrier of the pn junction, a decrease in the effective forward voltage (Vf) of the pn junction diode is suppressed. Therefore, the forward current flow through the pn junction diode is suppressed.

If, for example, the depth of the body region 26 is increased, there is a possibility that the forward current of the SBD cannot sufficiently flow to the bottom of the body region 26. When the forward current cannot flow sufficiently to the bottom of the body region 26, the effective forward voltage (Vf) of the pn junction diode becomes low and the forward current begins to flow through the pn junction diode. As a result, the reliability of the MOSFET 900 is lowered due to the growth of stacking faults in the silicon carbide layer.

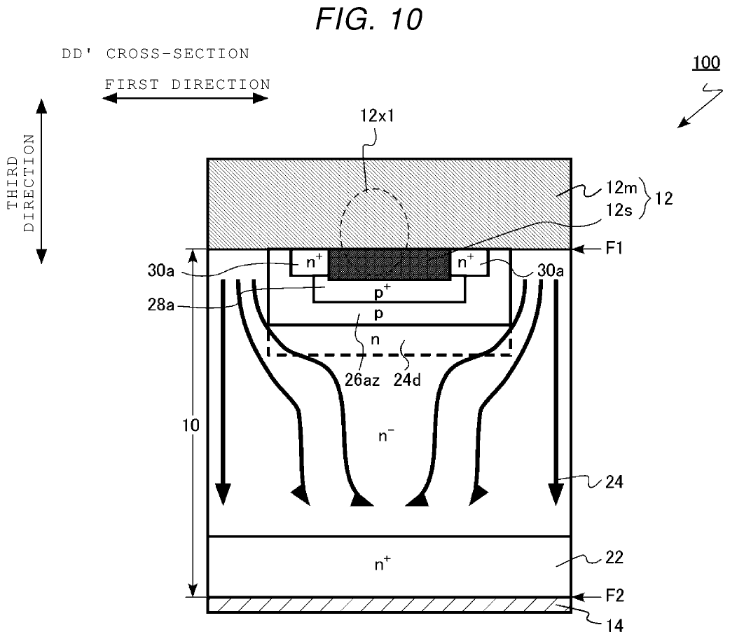

FIG. 10 is a diagram for illustrating the operation and effects of the semiconductor device of the first embodiment. FIG. 10 is a schematic cross-sectional view of the MOSFET 100 of the first embodiment. FIG. 10 is a diagram corresponding to FIG. 5 of the first embodiment.

In the MOSFET 100 of the first embodiment, the first body region 26a below the first contact electrode portion 12x1 includes the shallow region 26az. The drift region 24 also includes the third CSL region 24d.

Since the first body region 26a includes the shallow region 26az, the depth of the first body region 26a adjacent to the SBD in the first direction is shallow. Therefore, the forward current of the SBD flowing into the bottom of the body region 26 increases.

An increase in the forward current of the SBD that flows into the bottom of the body region 26 can suppress a decrease in the effective forward voltage (Vf) of the pn junction diode. Therefore, it is possible to suppress the forward current flow through the pn junction diode. Therefore, the growth of stacking faults in the silicon carbide layer is suppressed, and the reliability of the MOSFET 100 is improved.

From the viewpoint of increasing the forward current flowing into the bottom of the body region 26, the n-type impurity concentration of the third CSL region 24d is preferably higher than the n-type impurity concentration of the main region 24a. The n-type impurity concentration of the third CSL region 24d is preferably higher than the n-type impurity concentration of the first CSL region 24b and the n-type impurity concentration of the second CSL region 24c. From the viewpoint of increasing the forward current flowing into the bottom of the body region 26, the n-type impurity concentration of the third CSL region 24d is preferably 1.5 times or more the n-type impurity concentration of the first CSL region 24b and the n-type impurity concentration of the second CSL region 24c, more preferably 2 times or more, and even more preferably 5 times or more.

From the viewpoint of increasing the forward current flowing into the bottom of the body region 26, the depth of the shallow region 26az (d1 in FIG. 3) is preferably one half or less of the depth of the first deep region 26ax (d2 in FIG. 3) and the depth of the second deep region 26ay (d2 in FIG. 3), and more preferably one-third or less.

From the viewpoint of increasing the forward current flowing into the bottom of the body region 26, the distance in the second direction between the first deep region 26ax and the second deep region 26ay (d3 in FIG. 3) is preferably greater than the distance in the second direction between the first body region 26a and the second body region 26b (d4 in FIG. 3). From the viewpoint of increasing the forward current flowing around the bottom of the body region 26, the distance in the second direction between the first deep region 26ax and the second deep region 26ay (d3 in FIG. 3) is preferably 1.2 times or more and more preferably 1.5 times or more the distance in the second direction between the first body region 26a and the second body region 26b (d4 in FIG. 3).

The depth of the first deep region 26ax and the depth of the second deep region 26ay are preferably 1.5 μm or more. By setting the depth of the first deep region 26ax and the depth of the second deep region 26ay to 1.5 μm or more, for example, when a short circuit occurs in the load of the MOSFET 100, the short-circuit current flowing through the MOSFET 100 can be suppressed. Therefore, the short-circuit resistance of the MOSFET 100 is improved.

In the MOSFET 100 of the first embodiment, the diode electrode portion 12y and the contact electrode portion 12x are adjacent to each other in the second direction, so that a transistor-operating region is provided in the second direction of the diode electrode portion 12y that does not operate as a transistor. Therefore, the regions through which the on-current of the transistor flows are dispersed, and the on-current of the MOSFET 100 increases.

As described above, according to the first embodiment, the above-described effect, that is, a MOSFET with improved reliability is achieved.

### Second Embodiment

A semiconductor device according to a second embodiment differs from the semiconductor device according to the first embodiment in that the second contact electrode portion 12x2 is positioned in the second direction of the first contact electrode portion 12x1. In the following, a part of description may be omitted for contents that overlap with the first embodiment.

The semiconductor device of the second embodiment is a planar gate type vertical MOSFET 200 using silicon carbide. The MOSFET 200 of the second embodiment is a DIMOSFET. The MOSFET 200 of the second embodiment includes an SBD as a built-in diode.

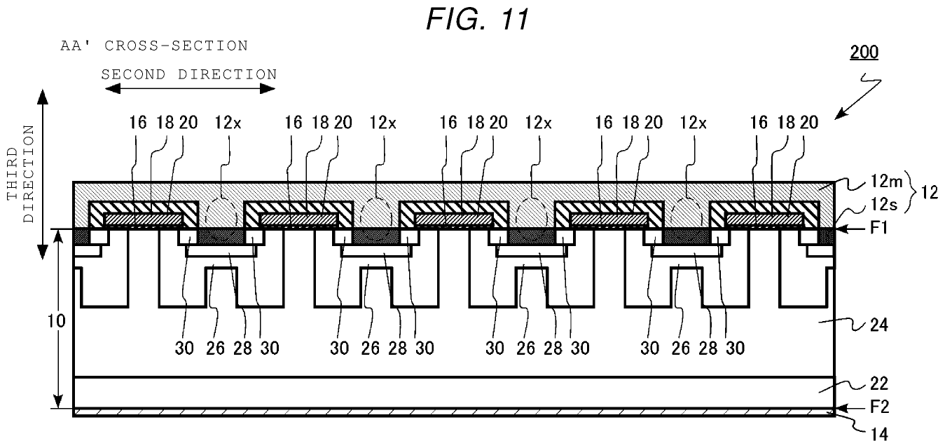

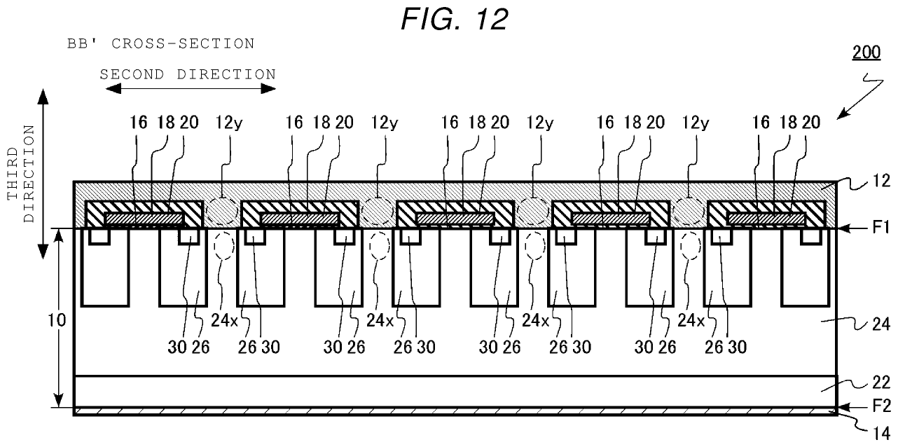

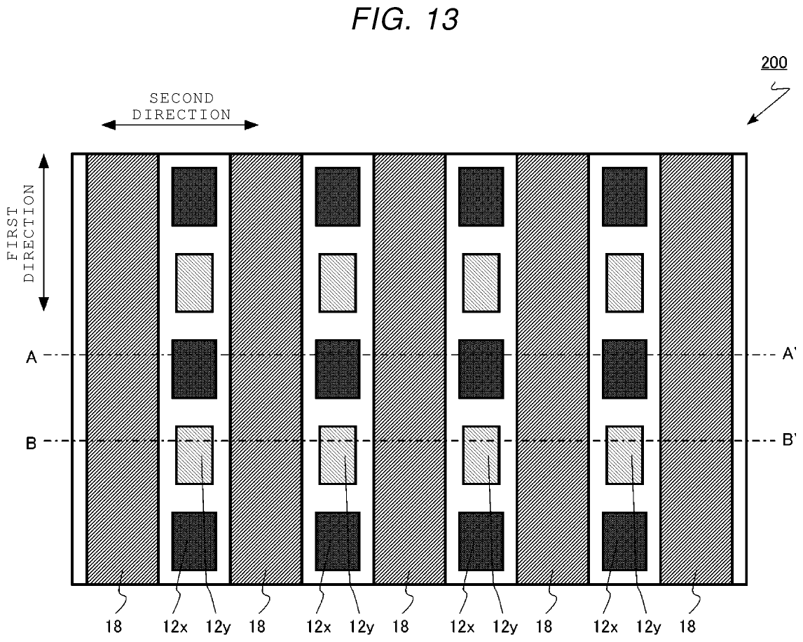

FIGS. 11 and 12 are schematic cross-sectional views of the semiconductor device according to the second embodiment. FIG. 13 is a schematic top view of the semiconductor device of the second embodiment. FIG. 13 is a schematic diagram illustrating patterns of gate electrodes and source electrodes on the upper surface of the silicon carbide layer. FIG. 11 is a cross-sectional view taken along line AA′ of FIG. 13. FIG. 12 is a cross-sectional view taken along line BB′ of FIG. 13.

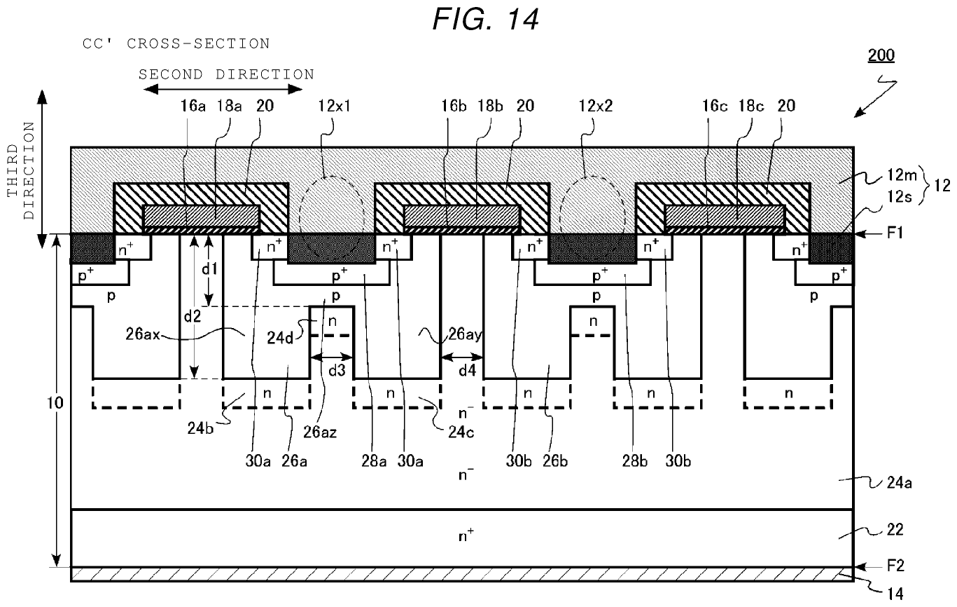

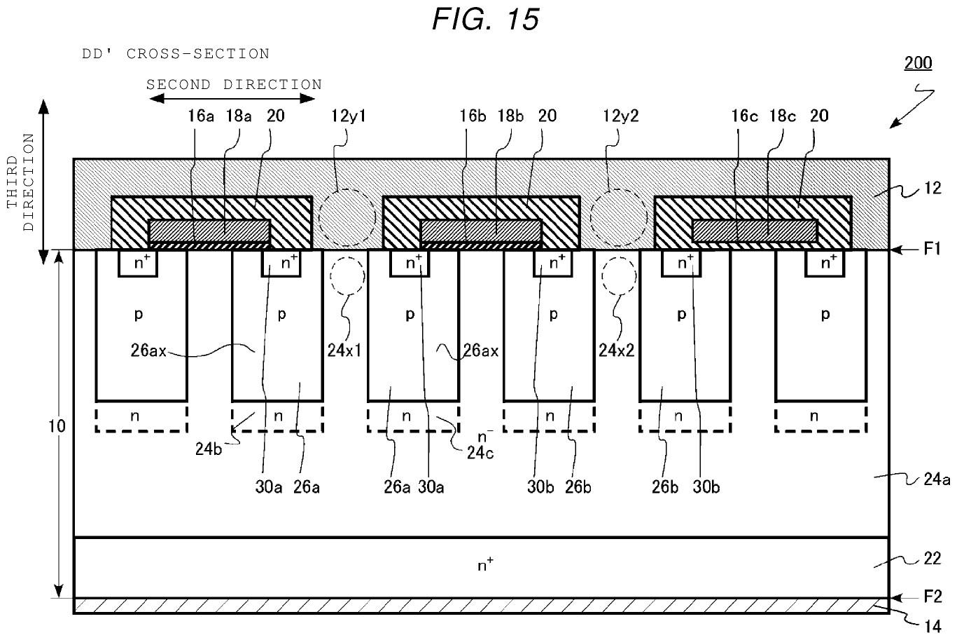

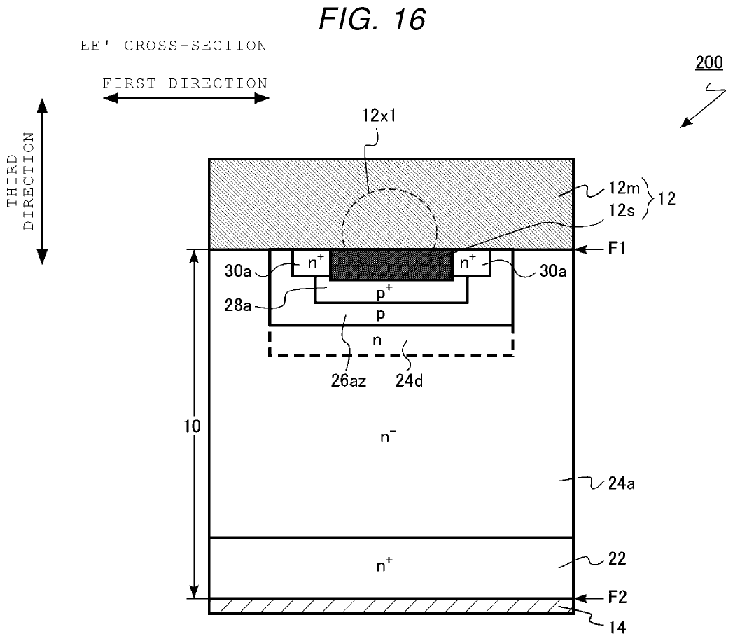

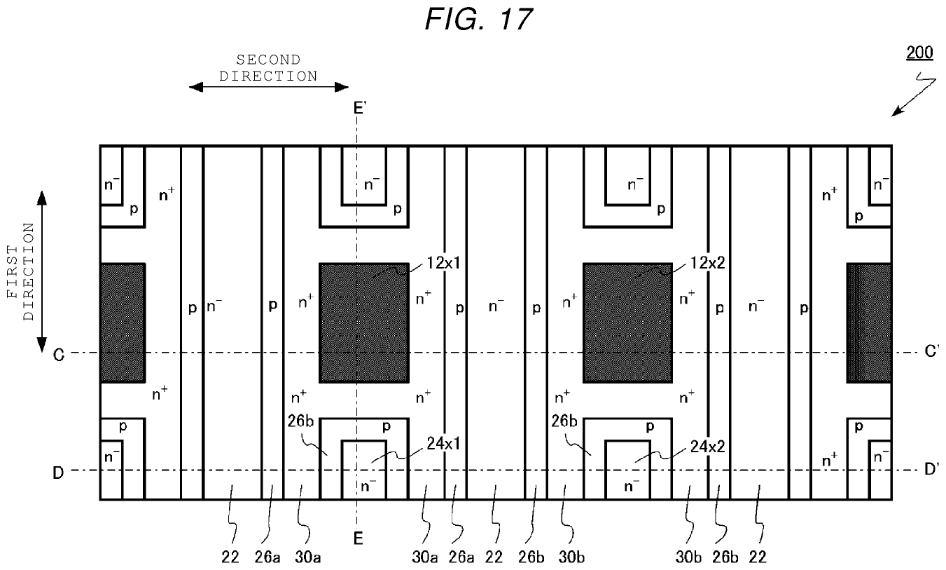

FIGS. 14, 15, and 16 are enlarged schematic cross-sectional views of the semiconductor device of the second embodiment. FIG. 17 is an enlarged schematic top view of the semiconductor device of the second embodiment. FIG. 17 is a diagram illustrating a pattern of the semiconductor region on the upper surface of the silicon carbide layer. FIG. 14 is a cross-sectional view taken along line CC′ of FIG. 17. FIG. 15 is a cross-sectional view taken along line DD′ of FIG. 17. FIG. 16 is a cross-sectional view taken along line EE′ of FIG. 17.

The MOSFET 200 includes a silicon carbide layer 10, a source electrode 12, a drain electrode 14, a gate insulating layer 16, a gate electrode 18, and an interlayer insulating layer 20. The source electrode 12 includes a metal silicide layer 12s and a metal layer 12m. The source electrode 12 includes a contact electrode portion 12x and a diode electrode portion 12y. The contact electrode portion 12x includes a first contact electrode portion 12x1 and a second contact electrode portion 12x2. The diode electrode portion 12y includes a first diode electrode portion 12y1 and a second diode electrode portion 12y2. The gate insulating layer 16 includes a first gate insulating layer 16a, a second gate insulating layer 16b, and a third gate insulating layer 16c. The gate electrode 18 includes a first gate electrode 18a, a second gate electrode 18b, and a third gate electrode 18c.

The silicon carbide layer 10 includes an n⁺-type drain region 22, an n⁻-type drift region 24, a p-type body region 26, a p⁺-type body contact region 28, and an n⁺-type source region 30. The p-type body region 26 includes a p-type first body region 26a and a p-type second body region 26b. The p⁺-type body contact region 28 includes a p⁺-type first body contact region 28a and a p⁺-type second body contact region 28b. The n⁺-type source region 30 includes an n⁺-type first source region 30a (and an n⁺-type second source region 30b.

The drift region 24 includes a main region 24a, a first CSL region 24b, a second CSL region 24c, and a third CSL region 24d.

The drift region 24 includes a JBS region 24x. The JBS region 24x includes a first JBS region 24x1 and a second JBS region 24x2.

The first body region 26a includes a first deep region 26ax, a second deep region 26ay, and a shallow region 26az.

The first diode electrode portion 12y1 is provided between the first gate electrode 18a and the second gate electrode 18b. The first diode electrode portion 12y1 is spaced in the first direction from the first contact electrode portion 12x1. The first diode electrode portion 12y1 contacts the first JBS region 24x1 of the drift region 24.

The second diode electrode portion 12y2 is provided between the second gate electrode 18b and the third gate electrode 18c. The second diode electrode portion 12y2 is spaced in the first direction from the second contact electrode portion 12x2. The second diode electrode portion 12y2 contacts the second JBS region 24x2 of the drift region 24.

In the MOSFET 200, another diode electrode portion 12y is positioned in the second direction with respect to the diode electrode portion 12y. Another contact electrode portion 12x is positioned in the second direction with respect to the contact electrode portion 12x.

For example, the second diode electrode portion 12y2 is positioned in the second direction with respect to the first diode electrode portion 12y1. For example, the second contact electrode portion 12x2 is positioned in the second direction with respect to the first contact electrode portion 12x1.

As described above, according to the second embodiment, a MOSFET with improved reliability is achieved by the same operations and effects as those of the first embodiment.

The first and second embodiments describe a case where the crystal structure of SiC is 4H—SiC as an example, but the present disclosure is applicable to devices using SiC having other crystal structures such as 6H—SiC and 3C—SiC. It is also possible to apply a plane other than the (0001) plane to the upper surface of the silicon carbide layer 10.

In the first and second embodiments, a case where the first conductive form is n-type and the second conductive form is p-type was described as an example, but it is also possible that the first conductivity type is p-type and the second conductivity type is n-type.

Although aluminum (Al) is given as an example of the p-type impurity in the first and second embodiments, boron (B) may also be used. Nitrogen (N) and phosphorus (P) are given as examples of the n-type impurities, but arsenic (As), antimony (Sb), and the like may also be applied.

In the first and second embodiments, a so-called planar gate structure in which each gate electrode is provided on the first surface F1 of the silicon carbide layer 10 is given as an example. However, it is also possible to apply a trench gate structure in which a trench is formed in the silicon carbide layer 10 and the gate electrode is provided in the trench.

The present disclosure may also be applied to an insulated gate bipolar transistor (IGBT).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a silicon carbide layer including a first surface and a second surface on opposite sides of the silicon carbide layer,
the silicon carbide layer including
a first silicon carbide region of a first conductivity type,
a second silicon carbide region of a second conductivity type provided between the first silicon carbide region and the first surface,
a third silicon carbide region of the second conductivity type provided between the second silicon carbide region and the first surface and having a second conductivity type impurity concentration higher than a second conductivity type impurity concentration of the second silicon carbide region, and
a fourth silicon carbide region of the first conductivity type provided between the second silicon carbide region and the first surface,
a first gate electrode extending in a first direction parallel to the first surface and facing the second silicon carbide region;
a second gate electrode extending in the first direction, spaced from the first gate electrode in a second direction parallel to the first surface and perpendicular to the first direction, and facing the second silicon carbide region;
a first gate insulating layer provided between the second silicon carbide region and the first gate electrode;
a second gate insulating layer provided between the second silicon carbide region and the second gate electrode;
a first electrode provided on the first surface side of the silicon carbide layer,
the first electrode including
a first portion provided between the first gate electrode and the second gate electrode and in contact with the third silicon carbide region and the fourth silicon carbide region; and
a second portion provided between the first gate electrode and the second gate electrode, spaced from the first portion in the first direction, and in contact with the first silicon carbide region, and
a second electrode provided on the second surface side of the silicon carbide layer, wherein
the first silicon carbide region includes a first region, and second, third, and fourth regions provided between the first region and the second silicon carbide region,
a first conductivity type impurity concentration of the second region is higher than a first conductivity type impurity concentration of the first region,
a first conductivity type impurity concentration of the third region is higher than the first conductivity type impurity concentration of the first region,
the second silicon carbide region includes a fifth region facing the first gate electrode, a sixth region facing the second gate electrode, and a seventh region provided between the fifth region and the sixth region and having a shallower depth than a depth of the fifth region and a depth of the sixth region,
the second region is provided between the first region and the fifth region,
the third region is provided between the first region and the sixth region, and
the fourth region is provided between the first region and the seventh region.

2. The semiconductor device according to claim 1, wherein
a first conductivity type impurity concentration of the fourth region is higher than the first conductivity type impurity concentration of the first region.

3. The semiconductor device according to claim 2, wherein
the first conductivity type impurity concentration of the fourth region is higher than the first conductivity type impurity concentration of the second region; and
the first conductivity type impurity concentration of the fourth region is higher than the first conductivity type impurity concentration of the third region.

4. The semiconductor device according to claim 3, wherein
the first conductivity type impurity concentration of the fourth region is twice or more the first conductivity type impurity concentration of the second region; and
the first conductivity type impurity concentration of the fourth region is twice or more the first conductivity type impurity concentration of the third region.

5. The semiconductor device according to claim 1, wherein
the depth of the fifth region is 1.5 μm or more, and
the depth of the sixth region is 1.5 μm or more.

6. The semiconductor device according to claim 1, wherein
the depth of the seventh region is one-half or less the depth of the fifth region; and
the depth of the seventh region is one-half or less the depth of the sixth region.

7. The semiconductor device according to claim 1, further comprising:
a third gate electrode extending in the first direction, spaced from the second gate electrode in the second direction, so that the second gate electrode is between the first gate electrode and the third gate electrode; and
a third gate insulating layer, wherein
the silicon carbide layer further includes
a fifth silicon carbide region of the second conductivity type provided between the first silicon carbide region and the first surface and separated from the second silicon carbide region in the second direction,
a sixth silicon carbide region of the second conductivity type provided between the fifth silicon carbide region and the first surface and having a second conductivity type impurity concentration higher than a second conductivity type impurity concentration of the fifth silicon carbide region, and
a seventh silicon carbide region of the first conductivity type provided between the fifth silicon carbide region and the first surface,
the second gate electrode faces the fifth silicon carbide region,
the second gate insulating layer is provided between the fifth silicon carbide region and the second gate electrode,
the third gate electrode faces the fifth silicon carbide region,
the third gate insulating layer is provided between the fifth silicon carbide region and the third gate electrode, and
the first electrode further includes a third portion provided between the second gate electrode and the third gate electrode and in contact with the sixth silicon carbide region and the seventh silicon carbide region.

8. The semiconductor device according to claim 7, wherein
a distance in the second direction between the fifth region and the sixth region is larger than a distance in the second direction between the second silicon carbide region and the fifth silicon carbide region.

9. The semiconductor device according to claim 7, wherein
the third portion is aligned with the second portion in the second direction.

10. The semiconductor device according to claim 1, wherein
the first surface is between the first gate electrode and the second silicon carbide region, and between the second gate electrode and the second silicon carbide region.

11. The semiconductor device according to claim 1, wherein
the seventh region is provided between the third silicon carbide region and the fourth region.

12. A semiconductor device comprising:
a silicon carbide layer including a first surface and a second surface on opposite sides of the silicon carbide layer, the silicon carbide layer including
a first silicon carbide region of a first conductivity type,
a second silicon carbide region of a second conductivity type provided between the first silicon carbide region and the first surface,
a third silicon carbide region of the second conductivity type provided between the second silicon carbide region and the first surface and having a second conductivity type impurity concentration higher than a second conductivity type impurity concentration of the second silicon carbide region, and
a fourth silicon carbide region of the first conductivity type provided between the second silicon carbide region and the first surface,
a first gate electrode extending in a first direction parallel to the first surface and facing the second silicon carbide region;
a second gate electrode extending in the first direction, spaced from the first gate electrode in a second direction parallel to the first surface and perpendicular to the first direction, and facing the second silicon carbide region;
a first gate insulating layer provided between the second silicon carbide region and the first gate electrode;
a second gate insulating layer provided between the second silicon carbide region and the second gate electrode;
a first electrode provided on the first surface side of the silicon carbide layer and having a plurality of first portions in contact with the third silicon carbide region and the fourth silicon carbide region and a plurality of second portions in contact with the first silicon carbide region; and
a second electrode provided on the second surface side of the silicon carbide layer, wherein
the first silicon carbide region includes a first region, and second, third, and fourth regions provided between the first region and the second silicon carbide region,
a first conductivity type impurity concentration of the second region is higher than a first conductivity type impurity concentration of the first region,
a first conductivity type impurity concentration of the third region is higher than the first conductivity type impurity concentration of the first region,
the second silicon carbide region includes a fifth region facing the first gate electrode, a sixth region facing the second gate electrode, and a seventh region provided between the fifth region and the sixth region and having a shallower depth than a depth of the fifth region and a depth of the sixth region,
the second region is provided between the first region and the fifth region,
the third region is provided between the first region and the sixth region, and
the fourth region is provided between the first region and the seventh region.

13. The semiconductor device according to claim 12, further comprising:
a third gate electrode extending in the first direction and facing the second silicon carbide region, wherein the third gate electrode is spaced from the second gate electrode in the second direction so that the second gate electrode is between the first gate electrode and the third gate electrode; and
a third gate insulating layer provided between the second silicon carbide region and the third gate electrode, wherein
the plurality of the first portions of the first electrode and the plurality of the second portions of the first electrode are arranged alternately in at least one of the first and second directions.

14. The semiconductor device according to claim 13, wherein
the plurality of the first portions of the first electrode and the plurality of the second portions of the first electrode are arranged alternately in both the first and second directions.

15. The semiconductor device according to claim 13, wherein
the plurality of the first portions of the first electrode and the plurality of the second portions of the first electrode are arranged alternately in the first direction but not in the second direction.

16. The semiconductor device according to claim 12, wherein
the plurality of the first portions of the first electrode extend into the first surface of the silicon carbide layer.

17. The semiconductor device according to claim 12, wherein
a first conductivity type impurity concentration of the fourth region is higher than the first conductivity type impurity concentration of the first region.

18. The semiconductor device according to claim 17, wherein
the first conductivity type impurity concentration of the fourth region is higher than the first conductivity type impurity concentration of the second region; and
the first conductivity type impurity concentration of the fourth region is higher than the first conductivity type impurity concentration of the third region.

19. The semiconductor device according to claim 18, wherein
the first conductivity type impurity concentration of the fourth region is twice or more the first conductivity type impurity concentration of the second region; and
the first conductivity type impurity concentration of the fourth region is twice or more the first conductivity type impurity concentration of the third region.

20. The semiconductor device according to claim 12, wherein
the depth of the seventh region is one-half or less the depth of the fifth region; and
the depth of the seventh region is one-half or less the depth of the sixth region.
